(19) United States
(12) Patent Application Publication
(10) Pub. No.: US 2006/0260841 A1
(43) Pub. Date: Nov. 23, 2006

(54) Arrangement for enclosing an object

(76) Inventors: Christopher James Fitzgerald, Clare (IE); Thomas Stephan Geraghty, Clare (IE); Jason Mulligan, Clare (IE); Thilo Simonsohn, Munich (DE)

Correspondence Address: BARLEY SNYDER, LLC, 1000 WESTLAKES DRIVE, SUITE 275, BERWYN, PA, 19312, US

(21) Appl. No.: 10/568,482

(22) PCT Filed: Jul. 28, 2004
(86) PCT No.: PCT/GB04/03248

§ 371 Date: Feb. 15, 2006

(30) Foreign Application Priority Data
Aug. 15, 2003 (GB) 0319222.6

(51) Int. Cl. H01L 23/48

(52) U.S. Cl. 174/532

(57) ABSTRACT

An arrangement for enclosing at least a part of an object, comprising an elastically deformable sleeve (3) and a support (5) by which the sleeve is held in a deformed state such that removal of the sleeve from one end of the support allows the sleeve to recover around and thereby to enclose an object (present in use), characterised in that an initiating part (13) of the sleeve remote from the said one end is arranged (preferably deformed over a flange (15) of the support), such that the deformation of that initiating part (13) may be locally relaxed (preferably by manual release of a holding portion (17) of the sleeve adjacent to the initiating part (13) thereof) initially in isolation from the remainder of the sleeve (3), the arrangement being such that the local relaxation provides an impetus that facilitates or causes the said removal of the sleeve (3) from the said one end of the support (5).

The present invention relates to an arrangement for enclosing at least part of an object, especially an elongate object. The object may, for example, comprise one or more electrical or communications cables, e.g. a joint between two or more such cables, or a termination of such a cable.

Many methods are known for enclosing elongate objects such as cables. One class of methods is to provide an elastically expandable sleeve that has been expanded and is held on or in a support which retains the sleeve in its expanded state until the sleeve is allowed to contract or “recover” around the cables, thereby enclosing them. Examples of methods in this class are described in international patent application WO 91/16564, U.S. Pat. No. 5,753,861 and U.S. Pat. No. 6,245,999 B1. A major problem associated with such methods is the general difficulty of removing the expanded sleeve from the support to enable the sleeve to enclose the cables. Because of this difficulty, some methods contract the sleeve without removing it from the support. However, while these methods solve the problem of how to remove the sleeve from the support they create other problems, namely of how to allow the sleeve to contract if the support is not removed from the sleeve, and how to accommodate the support in such cases.

In WO 91/16564, a recoverable elastomeric sleeve is provided in an expanded condition on a hollow cylindrical mandrel that has longitudinally extending projections spaced apart around the external circumference of the mandrel. The projections are intended to facilitate the withdrawal of the mandrel from the sleeve, and a lubricant may be provided to make such withdrawal easier. Even with such aids, withdrawal of the mandrel from the sleeve requires the manipulation of the mandrel, including rotating the mandrel within the sleeve in order to coat the internal surface of the sleeve with the lubricant. The presence of the lubricant between the contracted sleeve and the cable may not be desirable.

U.S. Pat No. 5,753,861 discloses an arrangement whereby an expanded sleeve is provided on a cylindrical support in such a way that the ends of the sleeve are folded back. In order to install the sleeve around a cable joint, the folded back ends of the sleeve are unfolded such that they extend beyond the ends of the support and thus contract around the cables. The support is therefore retained within the sleeve rather than being removed. Consequently, the problem of the difficulty of removing the support from the sleeve is obviated, but at the cost of retaining the support within the sleeve, and hence this arrangement might be regarded as a compromise.

In U.S. Pat. No. 6,245,999 B1, the ends of the expanded sleeve are also folded back, but an inner holdout member on which the sleeve is provided includes a longitudinally extending slit by which the holdout member may collapse under the action of a radial contracting force. Consequently, the holdout member is retained within the sleeve, but in a contracted configuration. This arrangement might also therefore be regarded as a compromise.

The present invention seeks to provide an improved arrangement and kit for enclosing at least part of an object, e.g. an elongate object such as a cable (or more than one cable). The invention also provides improved methods for assembling the kit to provide the arrangement, and for enclosing the object by means of the arrangement.

Accordingly, a first aspect of the invention provides an arrangement for enclosing at least a part of an object, comprising an elastically deformable sleeve and a support by which the sleeve is held in a deformed state such that removal of the sleeve from the support allows the sleeve to recover and thereby to enclose an object, an initiating part of the sleeve being arranged such that the deformation of that part may be locally relaxed initially in isolation from the remainder of the sleeve, the arrangement being such that the local relaxation provides an impetus to cause the remainder of the sleeve to recover in a way that facilitates or causes the removal of the sleeve from the support.

In preferred forms, the invention may provide an arrangement for enclosing at least a part of an object, comprising an elastically deformable sleeve and a support by which the sleeve is held in a deformed state such that removal of the sleeve from one end of the support allows the sleeve to recover around and thereby to enclose an object (present in use), characterised in that an initiating part of the sleeve remote from the said one end is arranged such that the deformation of that initiating part may be locally relaxed initially in isolation from the remainder of the sleeve, the arrangement being such that the local relaxation provides an impetus that facilitates or causes the said removal of the sleeve from the said one end of the support.

It may be further preferred that a holding portion of the sleeve remote from the said one end of the support and beyond the said initiating part of the sleeve is in a more relaxed state than the initiating part of the sleeve, the relatively relaxed state of the holding portion of the sleeve at least contributing to the holding of the initiating part of the sleeve, and consequently also the remainder of the sleeve, in the deformed state. In especially convenient embodiments of the invention, the local relaxation of the initiating part of the sleeve may be caused by deformation, preferably manual deformation, of the said holding portion of the sleeve.

The invention has the advantage that by locally relaxing the deformation of the initiating part (only) of the sleeve, the sleeve may substantially “self-install”, i.e. automatically recover and remov itself from the support with little or no further manual assistance, thereby easing the installation of the sleeve on the cable or other object.

In embodiments where the initiating part of the sleeve is in a deformed (e.g. expanded and/or stretched) state due to the support, the adjacent holding portion of the sleeve may be in a partially or fully relaxed state due to an absence of the support or a smaller diameter (or other dimension) of the support next to the holding portion of the sleeve. Consequently, the relaxed holding portion of the sleeve may be folded over a part of the support, thereby retaining the initiating part of the sleeve in place on the support. By expanding or otherwise deforming, e.g. manually, the holding portion of the sleeve, such retention of the initiating part of the sleeve may be released, thereby triggering the removal of the sleeve from the support.

When the initiating part of the sleeve is locally relaxed, potential energy stored in the initiating part of the sleeve due to the elasticity of the sleeve may be converted to kinetic energy that overcomes the inertia of the remainder of the sleeve and (especially) the frictional forces between the remainder of the sleeve and the support, thereby triggering the release of the remainder of the sleeve from the support, and the relaxation of the entire sleeve (such that it recovers, for example).

In preferred embodiments of the invention, the initiating part of the sleeve is held by the support in a state of greater deformation (e.g. greater expansion, and/or a stretched state) than that of the remainder of the sleeve. Preferably the greater deformation of the initiating part of the sleeve is caused by at least one protrusion and/or depression of the support, for example a flange and/or a groove on the support. Such a flange or groove may extend substantially entirely around the periphery of the support; additionally or alternatively, such a protrusion or depression may be localised at a single area on the support (and there may be more than one such area on the support).

An advantage of the initiating part of the sleeve being held in a state of greater deformation (which may be called “over deformation”, or “over expansion”) than that of the remainder of the sleeve, is that a greater amount of potential energy will be stored due to the elasticity of the sleeve, which may be converted to a greater amount of kinetic energy when the initiating part is locally relaxed. Consequently, the reliability of the removal of the sleeve from the support may be increased, or less (or no) manual assistance for the removal of the sleeve may be required.

In some embodiments of the invention, a protrusion or depression may be movable with respect to the remainder of the support, to cause or allow the local relaxation of the initiating part of the sleeve. For example, the protrusion or depression may be movable substantially to remove the protrusion or depression, i.e. substantially to flatten it out. This may be achieved by releasing a locking device, or some other trigger mechanism, for example.

The arrangement may include a retaining member attached to the sleeve such that releasing the retaining member from the sleeve causes or allows the local relaxation of the initiating part of the sleeve. For example, the retaining member may be in the form of a tie wrap (or similar) located around the sleeve. The tie wrap or other retaining member may constrict the sleeve into a peripheral groove in the support, for example.

Preferably the sleeve is hollow and arranged to enclose at least part of an object (e.g. a cable or a cable joint) by encircling it. Most preferably, the sleeve is generally in the shape of a sleeve. The sleeve, in its relaxed state, may comprise a plurality of sections of differing shapes and/or sizes and/or configurations, each section arranged to enclose a respective section of the object. For example, the sleeve may be intended to enclose a cable “breakout” whereby the cores of a multi-core cable are separated, in which case the sleeve may include separate sections for each cable core, and a main section for the full diameter of the cable.

The sleeve preferably is formed from an elastomeric polymer material, for example a silicone elastomer.

In the arrangement, preferably all or part of the support is located inside the sleeve, thereby preventing the expanded sleeve from contracting, until the support is withdrawn from the sleeve. The support preferably is hollow, thereby allowing the support to be placed around the cable or other object so that the sleeve may relax (e.g. contract) onto the object. The support preferably is formed from a polymer material, e.g. ABS (but other materials, including metals, are suitable). The support preferably is substantially rigid.

The support preferably has a shape that facilitates the removal of the sleeve from the support once the initiating part of the sleeve has been locally relaxed. For example, the support (or a part thereof) may be tapered (or chamfered) to facilitate the removal of the sleeve therefrom.

A second aspect of the invention provides a kit of parts for assembling an arrangement according to the first aspect of the invention, comprising the elastically deformable sleeve and the support.

A third aspect of the invention provides a method of assembling a kit according to the second aspect of the invention, comprising deforming the sleeve and holding the sleeve in its deformed state by the support.

The method preferably further comprises the step of deforming (e.g. stretching and/or expanding) the initiating part of the sleeve to a greater degree than that of the remainder of the sleeve, and holding the initiating part of the sleeve in its state of greater deformation by means of the support.

A fourth aspect of the invention provides a method of enclosing an object by means of an arrangement according to the first aspect of the invention, comprising:
(i) placing the arrangement over the object;
(ii) locally relaxing the initiating part of the sleeve; and
(iii) causing or allowing the sleeve to be removed from the support and to recover and thereby to enclose the object.

Preferred embodiments of the invention will now be described, by way of example, with reference to the accompanying drawings, of which:

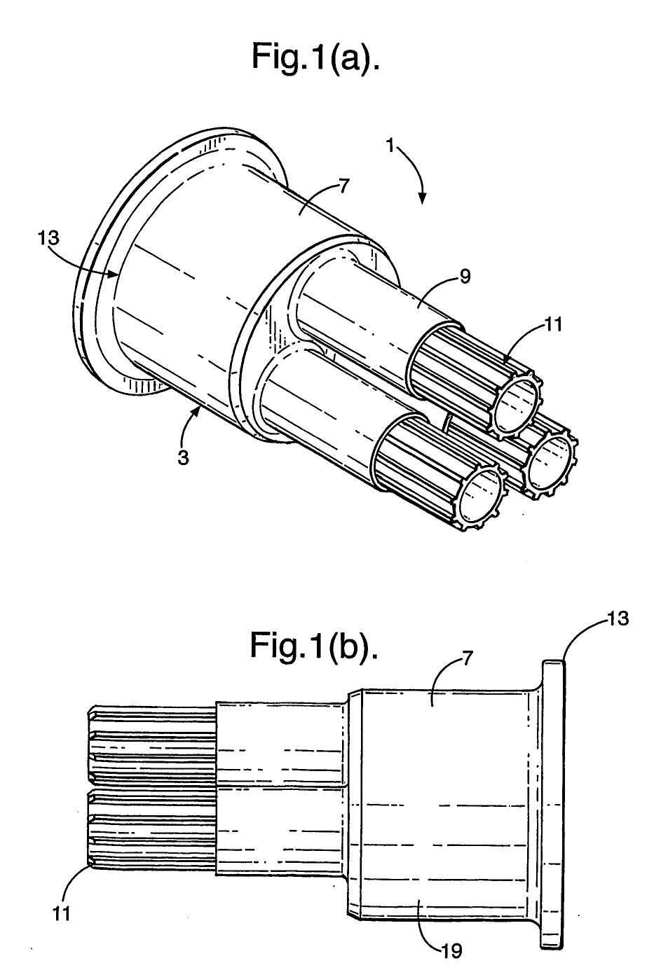

FIG. 1 (views (a) to (d)) shows a preferred embodiment of an arrangement according to the invention, in the form of a cable breakout;

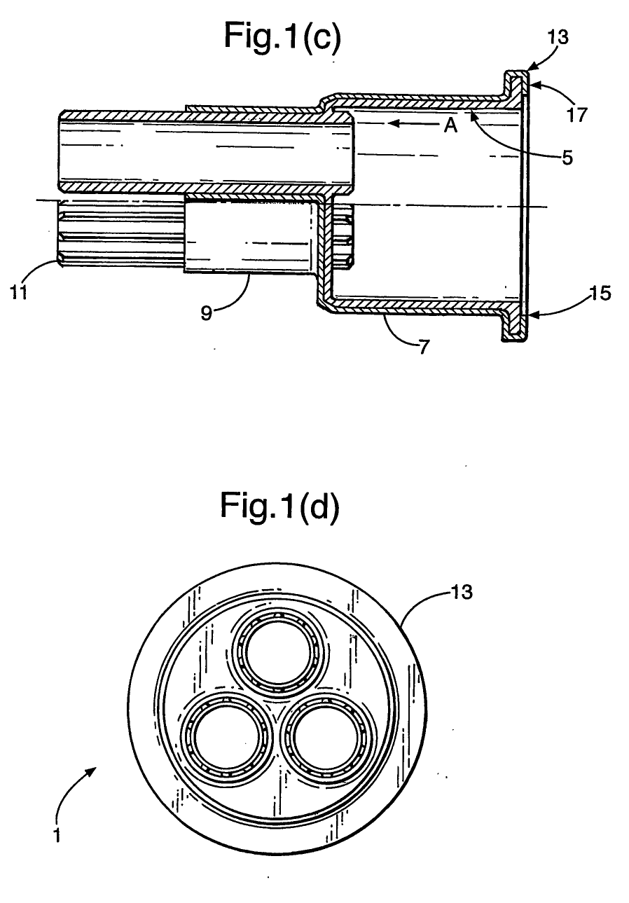

FIG. 2 (views (a) to (d)) shows, schematically, a process of over deforming a part of the sleeve of an arrangement according to the invention (e.g. the arrangement illustrated in FIG. 1), and subsequently locally relaxing that part of the sleeve such that it triggers the removal of the entire sleeve from the support;

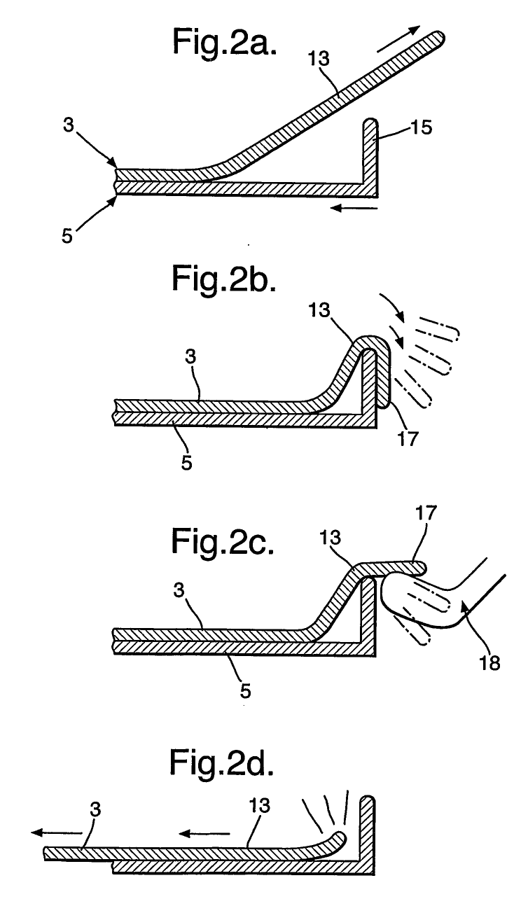

FIG. 3 (views (a) and (b)) shows, schematically, a movable protrusion of a support of a preferred embodiment of the invention; and

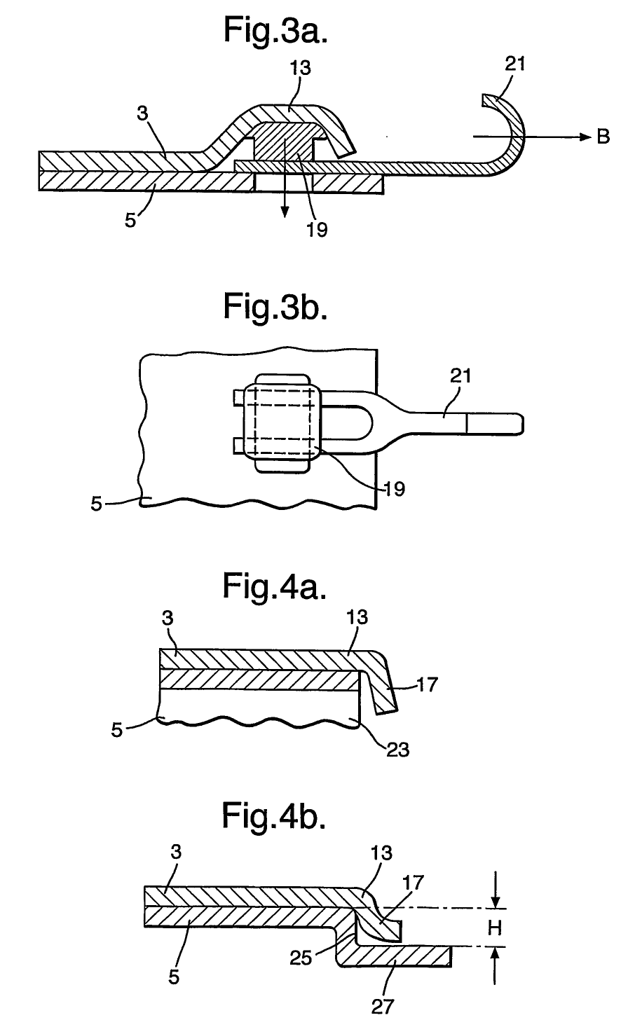

FIG. 4 (views (a) and (b)) shows, schematically, parts of two further preferred embodiments of the invention.

FIG. 1 shows a preferred embodiment of an arrangement 1 according to the invention. The arrangement 1 comprises an elastically expanded sleeve 3 held on a plurality of substantially rigid internal supports (or “holdouts”). The sleeve 3 is in the form of a sleeve for a cable breakout, and has a first main section 7 of relatively large diameter, and three minor sections 9 extending therefrom, of relatively small diameter. The main section 7 is for enclosing the end region of a three-core electrical power cable (not shown), and is held on a support 5 in accordance with the invention. The minor sections 9 are for individually enclosing the broken-out cores of the cable, and are individually held on separate conventional supports, or holdouts, 11.

A part 13 of the sleeve 3 extends over a peripheral flange 15 which projects radially outwardly from an end of the support 5, around an entire periphery of the support. It will be appreciated that in order for the elastically expandable sleeve 3 to extend over the flange 15 of the support, it has been stretched and expanded to a greater extent than has the remainder of the main section 7 of the sleeve 3. Adjacent to the initiating part 13 of the sleeve 3 is a portion 17 of the sleeve which is folded over the flange (and thus folded over the end of the sleeve). This adjacent portion 17 of the sleeve is therefore in a more relaxed state than that of the initiating part 13, and serves to retain the initiating part 13 in place on the flange 15 (and in its highly expanded and stretched condition).

In order to remove the section 7 of the sleeve 3 from the support 5, and allow the elastically expanded sleeve to relax and contract around the end of a cable, the adjacent portion 17 is merely expanded (preferably manually) sufficiently for the elasticity (i.e. the resilience) of the sleeve to cause the initiating part 13 of the sleeve to be released from the flange 15 and to relax locally. This local relaxation of the initiating part 13 of the sleeve then provides an impetus to cause the remainder of the sleeve section 7 to recover in a way that causes (or at least facilitates) the removal of the sleeve section 7 from the support 5. Preferably the potential energy released as kinetic energy by the release of the over-expanded and stretched initiating part 13 from the flange 15 overcomes the inertia of the sleeve section 7, and especially the frictional forces between the sleeve section 7 and the support 5, such that the elasticity of the sleeve section 7 forces the section 7 in the direction of the arrow A in view (c) of FIG. 1. This movement of the sleeve section 7 from the support is commonly known as “milk-off” (for its perceived resemblance to the action of milking a cow), and is facilitated by the support 5, or at least its external surface, being tapered in the direction of arrow A. In practice, the removal of the sleeve section 7 from the support 5 will generally be a combination of the sleeve moving away from the support 5 in the direction of arrow A, and the support 5 being forced out of the sleeve in the opposite direction, by the elastic recovery forces of the sleeve. If the leading end of the sleeve grips, or is by other means substantially prevented from moving along, a cable located within the expanded sleeve, the support 5 will be forced to move away from the sleeve in a direction opposite to direction A.

As already mentioned, the three minor sections 9 of the sleeve 3 are individually held in an expanded state by means of respective individual supports 11. The supports 11 preferably are removed from the sleeve in a conventional manner merely by withdrawing them manually. This is generally possible because the smaller diameters of the sections 9 give rise to lower contracting forces opposing their expansion, and therefore the individual supports 11 are easier to remove than is the larger support 5. Even so, it is generally desirable to provide aids to their removal, such as the illustrated external ribs, and possibly also lubricant provided on the external surfaces. Such ribs and/or lubricant may also be provided on the exterior of the support 5, to aid the removal of the sleeve section 7 therefrom.

Views (a) to (d) of FIG. 2 show, schematically, the main stages of the above described process of stretching the initiating part 13 of the sleeve around the flange 15, subsequently followed by triggering the release of the sleeve from the support by expanding the adjacent portion 17 of the sleeve. In view (a), the initiating part 13 is longitudinally stretched (in addition to its expansion to accommodate the support 5) so that it may extend over the flange 15. In view (b), the adjacent portion 17 is shown relaxing beyond the flange 15, thereby retaining the initiating part 13 in position on the flange in its “over deformed” state. View (c) shows the manual release (e.g. by finger 18) of the adjacent portion 17, leading to the relaxation of the initiating part 13 in view (d), which triggers the relaxation of the entire sleeve section.

FIG. 3 shows: (a) cross-sectional, and (b) plan views of a movable protrusion 19 of a preferred arrangement according to the invention. In this arrangement, instead of (or in addition to) a fixed flange (or the like) one or more such movable protrusions are provided. The protrusion 19 functions in exactly the same way as the flange 15 of FIGS. 1 and 2, but in this embodiment, in order locally to relax the initiating part 13 of the sleeve such that it triggers the removal of the sleeve from the support, a locking device 21 which locks the protrusion in its “protruding mode” is removed from the support (in the direction of arrow B) thereby allowing the expanded sleeve 3 to force the movable protrusion though the support such that it no longer protrudes significantly (i.e. its “non-protruding mode”) and thus causing the sleeve to relax and become removed from the support.

FIG. 4 (views (a) and (b)) schematically illustrates two embodiments of the invention which do not rely on an “over expansion” of the initiating part 13 of the sleeve. In each of these embodiments, the initiating part 13 near to an end of the sleeve is deformed no more (or not substantially more) than the remainder of the sleeve, but an adjacent portion 17 of the sleeve is folded over an end 23 of the support 5 (in view (a)) or over the lip 25 of a recess, or a reduced diameter section 27 of the sleeve (in view (b)) due to the elasticity of the sleeve. By expanding the adjacent portion 17, the initiating part 13 of the sleeve is allowed to relax, thereby triggering the recovery of the entire sleeve, and its removal from the support 5. For a given elasticity of the sleeve 3, the height H of the lip 25 determines the releasing force required to relax the initiating part 13 of the sleeve, and to trigger the recovery of the entire sleeve.

1. An arrangement for enclosing at least a part of an object, comprising:
an elastically deformable sleeve and a support by which the sleeve is held in a deformed state such that removal of the sleeve from one end of the support allows the sleeve to recover around and thereby to enclose the object;
an initiating part of the sleeve remote from the one end is arranged such that the deformation of the initiating part may be locally relaxed initially in isolation from a remainder of the sleeve, the arrangement being such that the local relaxation provides an impetus that facilitates or causes the removal of the sleeve from the one end of the support.

2. The arrangement according to claim 1, in which a holding portion of the sleeve remote from the one end of the support and beyond the initiating part of the sleeve is in a more relaxed state than the initiating part of the sleeve, the relatively relaxed state of the holding portion of the sleeve at least contributing to the holding of the initiating part of the sleeve, and consequently also the remainder of the sleeve, in the deformed state.

3. The arrangement according to claim 2, in which the local relaxation of the deformation of the initiating part of the sleeve may be caused by a deformation of the holding portion of the sleeve.

4. The arrangement according to claim 1, in which the initiating part of the sleeve is held by the support in a state of greater deformation than that of the remainder of the sleeve.

5. The arrangement according to claim 4, in which the greater deformation of the initiating part of the sleeve is caused by a protrusion or a depression of the support.

6. The arrangement according to claim 5, in which the protrusion is in the form of a flange or the depression is in the form of a groove.

7. The arrangement according to claim 5, in which the protrusion or the depression is movable with respect to the remainder of the support, to cause or allow the local relaxation of the initiating part of the sleeve.

8. The arrangement according to claim 1, further comprising a retaining member attached to the sleeve such that releasing the retaining member from the sleeve causes or allows the local relaxation of the initiating part of the sleeve.

9. The arrangement according to claim 1, in which the sleeve is hollow and arranged to enclose at least part of the object by encircling it.

10. The arrangement according to claim 9, in which the sleeve is generally in the shape of a round or oval tube.

11. The arrangement according to claim 9, in which the sleeve, in its relaxed state, comprises a plurality of sections of differing configurations, each of the sections arranged to enclose a respective section of the object.

12. The arrangement according to claim 9, in which all or part of the support is located inside the sleeve.

13. The arrangement according to claim 1, in which the support is hollow.

14. (canceled)

15. (canceled)

16. The arrangement according to claim 1, in which the sleeve is formed from an elastomeric polymer material.

17. The arrangement according to claim 1, in which the support is formed from a polymer material.

18. The arrangement according to claim 1, in which the deformation of the sleeve comprises expansion of the sleeve.

19. The arrangement according to claim 4, in which the state of greater deformation of the initiating part of the sleeve comprises a stretched or expanded state.

20. The arrangement according to claim 1, in which the support has a shape that facilitates the removal of the sleeve from the support once the initiating part of the sleeve has been locally relaxed.

21. The arrangement according to claim 20, in which the support is tapered to facilitate the removal of the sleeve therefrom.

22. The arrangement according to claim 1, in which the support carries lubricant material that facilitates the removal of the sleeve from the support once the initiating part of the sleeve has been locally relaxed.

23. The arrangement according to claim 1, in which the removal of the sleeve from the support is substantially automatic once the initiating part of the sleeve has been locally relaxed.

24. The method according to claim 27, in which the sleeve is elastically deformable.

25. The method according to claim 27, further comprising the step of deforming the sleeve and holding the sleeve in its deformed state by the support.

26. The method according to claim 25, further comprising the step of deforming the initiating part of the sleeve to a greater degree than that of the remainder of the sleeve, and holding the initiating part of the sleeve in its state of greater deformation by means of a suitable projection or other formation of the support.

27. A method of enclosing an object, comprising the steps of:
placing a support over the object;
locally relaxing an initiating part of the sleeve; and
causing the sleeve to be removed from the support and to recover and thereby enclose the object.
